(19) United States
(12) Patent Application Publication
(10) Pub. No.: US 2025/0353115 A1
(43) Pub. Date: Nov. 20, 2025

(54) LASER SEALING AND SURFACE ASPERITY CONTROLLING METHOD WITH CONTROLLED SOLIDIFICATION COOLING RATE

(71) Applicant: Robert Bosch GmbH, Stuttgart (DE)

(72) Inventors: Bo CHENG, Malden, MA (US); Stephanie KARG, Stuttgart (DE); Tobias Joachim MENOLD, Weil Der Stadt (DE); Mawuli AMETOWOBLA, Stuttgart (DE); Adina DAIS, Calw (DE); Jens FREY, Filderstadt (DE); David BORBELY, Budapest (HU); Charles TUFFILE, Swansea, MA (US)

(21) Appl. No.: 18/667,457

(22) Filed: May 17, 2024

(51) Int. Cl. B23K 26/352; B23K 26/06; B23K 26/067; B23K 26/073

(52) U.S. Cl. CPC B23K 26/3576; B23K 26/0626; B23K 26/0676; B23K 26/0736

(57) ABSTRACT

A method for controlling surface asperity during laser sealing of a membrane vent hole. The method includes applying a main pulse from a main laser to the membrane vent hole at a first time. The main pulse has a main pulse cross-sectional shape, a main pulse power profile, and a main pulse duration. The method further includes applying one or more supplemental pulses from one or more supplemental lasers to the membrane vent hole at a second time later than the first time. The one or more supplemental pulses have supplemental pulse cross-sectional shape(s), supplemental pulse power profile(s), and supplemental pulse duration(s). The first and second applying steps form a seal over the membrane vent hole. The seal includes a seal surface having a controlled surface asperity characteristic.

### TECHNICAL FIELD

The present disclosure relates to pulse laser irradiation techniques, and more specifically, laser sealing and surface asperity controlling methods for laser sealing of a membrane vent hole where the membrane may be formed of silicon and the method uses a controlled solidification cooling rate.

### BACKGROUND

A pulse laser irradiation technique has been proposed for sealing vent hole openings to form a seal zone in an inertial measurement unit (IMU) to capture critical sensor cavity pressures within a device. The vent hole is formed by deep reactive ion etching of a silicon membrane below which is a device chamber that contains a vacuum-level dependent micro-electromechanical system (MEMS) sensor. During the laser irradiation process, the seal zone quality can be significantly affected by complicated process physics, such as Marangoni flow and/or silicon phase changes. A solidified silicon topography can be problematic for IMU devices. For example, surface asperity may form rough edges on the surface of the seal zone. The removal of such structure may potentially damage the quality of the device.

### SUMMARY

According to one embodiment, a method for controlling surface asperity during laser sealing of a membrane vent hole is disclosed. The method includes applying a main pulse from a main laser to the membrane vent hole at a first time. The main pulse has a main pulse cross-sectional shape, a main pulse power profile, and a main pulse duration. The method further includes applying one or more supplemental pulses from one or more supplemental lasers to the membrane vent hole at a second time later than the first time. The one or more supplemental pulses have supplemental pulse cross-sectional shape(s), supplemental pulse power profile(s), and supplemental pulse duration(s). The first and second applying steps form a seal over the membrane vent hole. The seal includes a seal surface having a controlled surface asperity characteristic. In one or more embodiments, the one or more supplemental pulses may include a first supplemental pulse, a second supplemental pulse, a third supplemental pulse, and a fourth supplemental pulse. The main pulse power profile may be a main pulse non-constant power profile. The supplemental pulse power profiles may be supplemental pulse non-constant power profiles.

### BRIEF DESCRIPTION OF THE DRAWINGS

FIG. 1A depicts a cross-sectional view of device formed with a silicon membrane.

FIG. 1B depicts a cross-sectional, perspective, isolated view of a portion of a vent hole within the device.

FIGS. 1C and 1D show schematic side views of a laser irradiation process performed on the vent hole opening in a melted state and a solidified state, respectively.

FIG. 2A is a schematic, cross-sectional view of a melt domain of a substrate (e.g., a silicon substrate) upon application of a main laser.

FIG. 2B is a schematic, cross-sectional view of a solidification path of a solidified material of the substrate.

FIG. 2C is a schematic, cross-sectional view of a solidification path with the application of a supplemental laser.

FIG. 3A is a schematic, top view of a silicon substrate having a melt zone formed from a main laser (e.g., a Gaussian laser) to seal a venthole in the silicon substrate.

FIG. 3B is a graph showing the power of the main laser as a function of time step.

FIG. 3C is a schematic, top view of a silicon substrate having a melt zone formed from a main laser and supplemental lasers.

FIG. 3D is a graph showing the power of the main laser and the supplemental lasers.

FIG. 4A is a schematic, cutaway view of a substrate having a vent hole and a melt pool formed above the vent hole using the main laser of FIG. 3A.

FIG. 4B is a schematic, cross-sectional view of the substrate of FIG. 4A.

FIG. 4C is a schematic, cutaway view of a substrate having a vent hole and a melt pool formed above the vent hole using the main laser and the supplemental lasers of FIG. 3C.

FIG. 4D is a schematic, cross-sectional view of the substrate of FIG. 4C.

FIG. 4E is a schematic, perspective view of the substrate of FIGS. 4A and 4C showing isometric solidification paths depicted by arrows at time step 1.5.

FIG. 4F is a schematic, perspective view of the substrate of FIGS. 4A and 4C showing isometric solidification paths depicted by arrows at time step 2.0.

FIG. 4G is a schematic, perspective view of the substrate of FIGS. 4B and 4D showing isometric solidification paths depicted by arrows at time step 1.5 having relative SCR values of 0.64.

FIG. 4H is a schematic, perspective view of the substrate of FIGS. 4B and 4D showing isometric solidification paths depicted by arrows at time step 2.0 having relative SCR values of 0.2.

FIG. 4I is a schematic, perspective view of the substrate of FIGS. 4B and 4D showing isometric solidification paths depicted by arrows at time step 2.7 having relative SCR values of 0.15.

FIG. 4J is a schematic, perspective view of the substrate of FIGS. 4B and 4D showing isometric solidification paths depicted by arrows at time step 3.0 having relative SCR values of 0.4.

FIG. 5A is a schematic, cross-sectional view of the substrate of FIGS. 4A and 4C showing a tip height of 100% for the final solidified surface morphology.

FIG. 5B is a schematic, cutaway view of the substrate of FIGS. 4A and 4C showing the final solidified surface morphology.

FIG. 5C is a schematic, cross-sectional view of the substrate of FIGS. 4B and 4D showing a tip height of 50% for the final solidified surface morphology.

FIG. 5D is a schematic, cutaway view of the substrate of FIGS. 4B and 4D showing the final solidified surface morphology.

FIG. 6A is a graph plotting power as a function of time step for a main laser to obtain a main power curve.

FIG. 6B is an image depicting an end view of the main laser of FIG. 6A.

FIG. 6C is a graph plotting power as a function of time step for the main laser of FIG. 6A and one or more supplemental lasers to obtain main and supplemental power curves.

FIG. 6D is an image depicting the relative intensity of supplemental lasers with the darker regions having greater intensity than the lighter regions.

FIG. 6E is an image depicting the relative intensity of the main and supplemental lasers with the darker regions having greater intensity than the lighter regions.

FIG. 7A is a first perspective view depicting the results of the vent hole closing process using the first simulation case.

FIG. 7B is a second perspective view depicting the results of the vent hole closing process using the first simulation case.

FIG. 7C is a first perspective view depicting the results of the vent hole closing process using the second simulation case.

FIG. 7D is a second perspective view depicting the results of the vent hole closing process using the second simulation case.

FIG. 8A is a top view of six supplemental lasers evenly spaced around the periphery of a main laser above a substrate.

FIG. 8B is a top view of three supplemental lasers evenly spaced around the periphery of a main laser above the substrate shown in FIG. 8A.

FIG. 8C is a top view of six supplemental lasers unevenly spaced around the periphery of a main laser.

FIG. 8D is a top view of six supplemental lasers unevenly spaced around the periphery of a main laser where the supplemental lasers have varying diameters.

FIG. 9A depicts a graph showing a main laser profile and a supplemental laser profile where the supplemental laser profile may overlap or be spaced apart from main laser profile.

FIG. 9B depicts a graph showing a main laser profile and a supplemental laser profile where the power over time is non-constant.

FIG. 9C depicts a top view of six supplemental lasers spaced around the periphery of a main laser and having varying shapes.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the embodiments. As those of ordinary skill in the art will understand, various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the term “polymer” includes “oligomer,” “copolymer,” “terpolymer,” and the like; the description of a group or class of materials as suitable or preferred for a given purpose in connection with the invention implies that mixtures of any two or more of the members of the group or class are equally suitable or preferred; molecular weights provided for any polymers refers to number average molecular weight; description of constituents in chemical terms refers to the constituents at the time of addition to any combination specified in the description, and does not necessarily preclude chemical interactions among the constituents of a mixture once mixed; the first definition of an acronym or other abbreviation applies to all subsequent uses herein of the same abbreviation and applies mutatis mutandis to normal grammatical variations of the initially defined abbreviation; and, unless expressly stated to the contrary, measurement of a property is determined by the same technique as previously or later referenced for the same property.

This invention is not limited to the specific embodiments and methods described below, as specific components and/or conditions may, of course, vary. Furthermore, the terminology used herein is used only for the purpose of describing embodiments of the present invention and is not intended to be limiting in any way.

As used in the specification and the appended claims, the singular form “a,” “an,” and “the” comprise plural referents unless the context clearly indicates otherwise. For example, reference to a component in the singular is intended to comprise a plurality of components.

The term “substantially” may be used herein to describe disclosed or claimed embodiments. The term “substantially” may modify a value or relative characteristic disclosed or claimed in the present disclosure. In such instances, “substantially” may signify that the value or relative characteristic it modifies is within +0%, 0.1%, 0.5%, 1%, 2%, 3%, 4%, 5% or 10% of the value or relative characteristic.

In one or more embodiments, a method to reduce surface asperity of seal zones in laser sealing of silicon membranes is disclosed. One or more embodiments rely on a computational fluid dynamics (CFD) model to simulate a laser used in a silicon membrane sealing process. Complicated process physics such as surface tension and/or solidification volume shrinkage are considered in the CFD model. Temperature dependent material properties, such as density, conductivity, specific heat and/or surface tension coefficient, may be included in the CFD model to improve simulation accuracy.

In one or more embodiments, multi-physics numerical simulation is used to study the laser irradiation and melting of the silicon material for optimization of the process parameters to reduce or eliminate the solidified surface asperity. One or more embodiments thereby present novel laser irradiation methods or mechanisms to reduce or eliminate the solidified surface asperity in the inertial measurement unit (IMU) fabrication process.

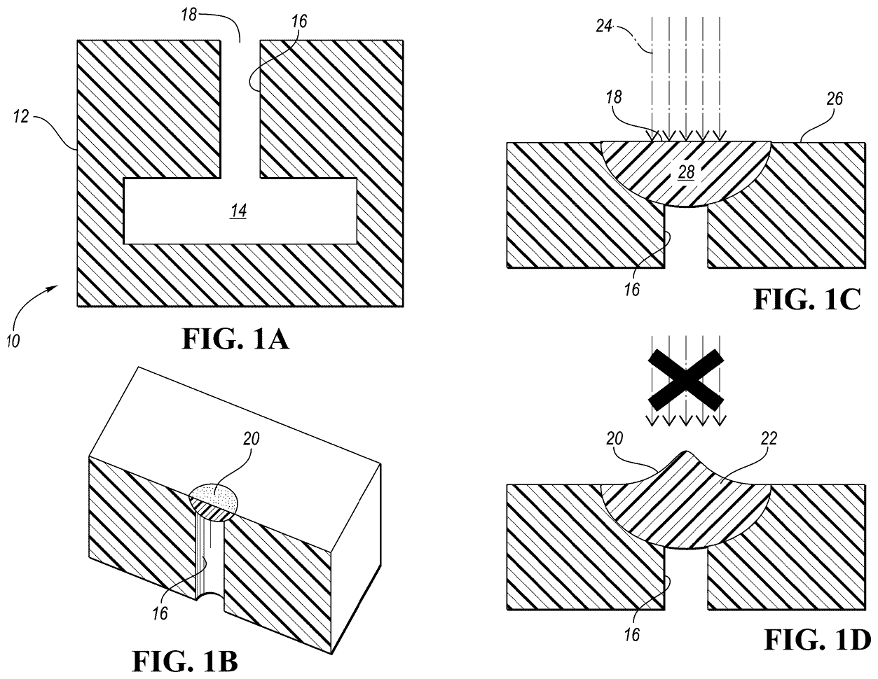

A multi-physics CFD model characterizes the complicated thermal fluid phenomenon in the vent hole sealing process. In one or more embodiments, the model includes a stationary laser irradiation heat source, solid to liquid phase transformation, solidification volume change, surface tension caused by Marangoni flow, evaporation pressure, and/or temperature dependent thermal fluid properties. The geometrical information of an IMU silicon membrane with a vent hole (e.g., the area of interest in FIG. 1B) may also be included.

A pulse laser irradiation technique may be utilized to seal a vent hole opening in an IMU. The IMU is configured to capture critical sensor cavity pressures within a device. FIG. 1A depicts a cross-sectional view of device 10 formed of material 12 (e.g., a silicon membrane). The material 12 defines device chamber 14 and vent hole 16. Vent hole 16 terminates at vent hole opening 18. Vent hole 16 extends between device chamber 14 and vent hole opening 18. FIG. 1B depicts a cross-sectional, perspective, isolated view of a portion of vent hole 16 within device 10. FIG. 1B depicts seal 20 configured to seal vent hole opening 18. Seal zone 18 is formed via a laser irradiation process.

When material 12 is a silicon membrane, vent hole 16 is formed by chemical etching of a silicon (Si) membrane below which device chamber 14 containing a pressure-sensitive micro-electromechanical system (MEMS) sensor. During the laser irradiation process, the silicon in the seal zone melts, flows, and resolidifies, during which the seal quality can be significantly affected by complicated process physics, such as Marangoni flow and Si phase changes. As the molten silicon solidifies, the volume increases, thereby reducing the density, resulting in the formation of a peak-shaped surface asperity.

FIGS. 1C and 1D show a schematic side view of a laser irradiation process performed on vent hole opening 18 in a melted state and a solidified state, respectively. The laser irradiation process forms seal 20, which has a surface abnormality shown in FIG. 1D. As shown in FIG. 1C, laser pulse 24 with a pulse duration is used to irradiate top surface 26 of the silicon membrane adjacent to vent hole 16. The material under irradiated region 28 starts to melt and flow to fill vent hole 16. After laser pulse 24 is turned off, as shown in FIG. 1D, the molten silicon solidifies and seals vent hole 16. However, as shown in FIG. 1D, surface asperity 22 is formed on seal 20.

One or more embodiments relate to a method for closing a vent hole while mitigating surface asperity. The surface morphology of a laser sealed membrane (e.g., silicon membrane) may be at least partially a function of a material solidification cooling rate (“SCR”). In one or more embodiments, the SCR may refer to a temperature drop for a period once the temperature decreases below a material solidus point, where the SCR in a melt pool (e.g., material in a liquidus state) is set to 0. In one or more embodiments, the surface morphology may be tailored by controlling the SCR (e.g., through an externally applied heating source).

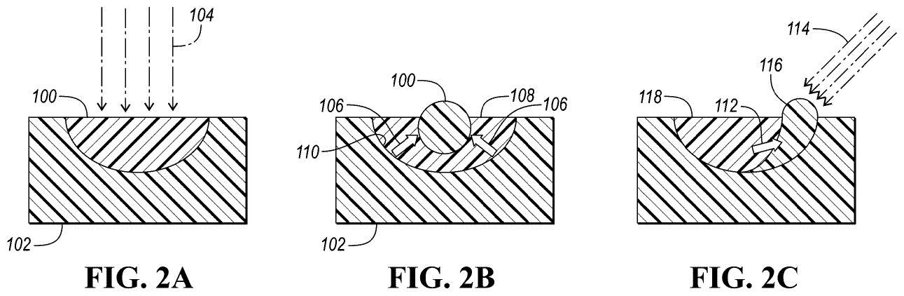

FIG. 2A is a schematic, cross-sectional view of melt domain 100 of substrate 102 (e.g., a silicon substrate) upon application of first laser 104. FIG. 2B is a schematic, cross-sectional view of solidification path 106 of solidified material 108 of substrate 102. As shown in FIG. 2B, melt domain 100 first solidifies from boundary area 110 and then gradually toward the center. FIG. 2C is a schematic, cross-sectional view of solidification path 112 with the application of second laser 114. With the application of additional second laser 114, melt domain 116 maintains a lower SCR (e.g., maintains a liquid form) at the region irradiated with second laser 114 while region 118 away from laser irradiation cools first. The use of second laser 114 changes the surface morphology as shown between FIG. 2B (center elevation morphology) and FIG. 2C (side elevation morphology). In one or more embodiments, the combination of laser spatial and temporal characteristics, the number of lasers, the laser incident angles, and/or other laser features, may produce desired surface morphologies.

In one or more embodiments, one or more lasers in addition to a first laser are used to control the SCR in a boundary region of a melt zone. This method may result in a higher SCR at a melt pool center and a lower SCR at a melt pool boundary. In one or more embodiments, the melt domain center surface tip height is reduced after spreading the last cooled zones around the melt pool boundary.

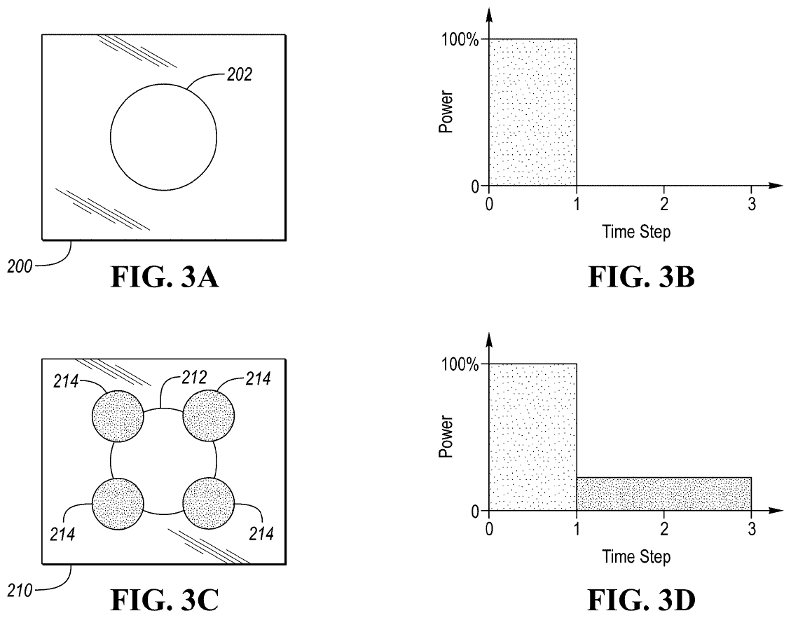

FIG. 3A is a schematic, top view of silicon substrate 200 having a melt zone formed from main laser 202 (e.g., a Gaussian laser) to seal a venthole in silicon substrate 200. Once the material of the melt zone is melted and flows to seal the venthole, the first laser is turned off. FIG. 3B is a graph showing the power of main laser 202 as a function of time step. As shown in FIG. 3B, main laser 202 is at 100% power during the first time step. The period for the time step may be one or more milliseconds, one or more microseconds, or one or nanoseconds, and range selecting to of these values.

FIG. 3C is a schematic, top view of silicon substrate 210 having a melt zone formed from main laser 212 and supplemental lasers 214. The diameter of each of the supplemental lasers 214 may be less than the diameter of main laser 212 by any of the following percentages or a range of any two of the following percentages: 5%, 10%, 15%, 20%, 25%, 30%, 35%, 40%, 45%, 50%, 55%, 60%, 65%, 70%, 75%, 80%, 85%, and 90%. The power of each of the supplemental lasers 214 may be less than the power of the diameter of main laser 212 by any of the following percentages or a range of any two of the following percentages: 5%, 10%, 15%, 20%, 25%, 30%, 35%, 40%, 45%, 50%, 55%, and 60%. FIG. 3D is a graph showing the power of main laser 212 and each of supplemental lasers 214 as a function of time step. As shown in FIG. 3D, main laser 212 is at 100% power during the first time step and at 0% power thereafter while each of supplemental lasers 214 is at 0% during the first time step and at 16.7% power during the second and third time steps. The configuration shown in FIG. 3C may enable a slower SCR at the melt pool boundary. The first main time step and the second supplemental time step may be varied depending on the embodiment. For instance, the first main time step may be 100% of a time step and the second supplemental time step may be any of the following or in a range of any two of the following time steps relative to the first time step: 50%, 75%, 100%, 125%, 150%, 175%, 200%, 225%, 250%, 275%, 300%, 325%, 350%, 375%, and 400%.

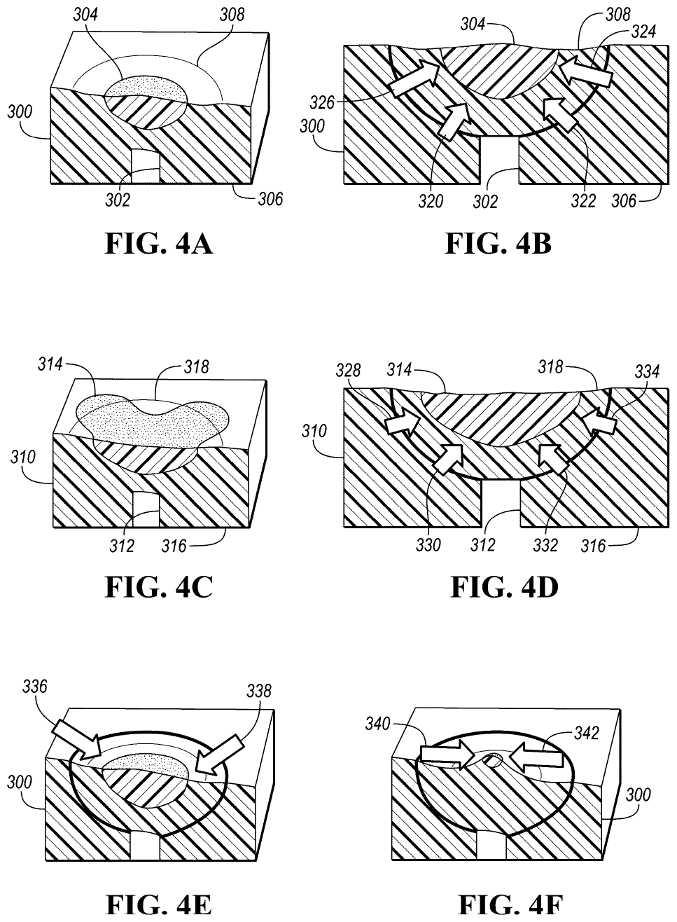

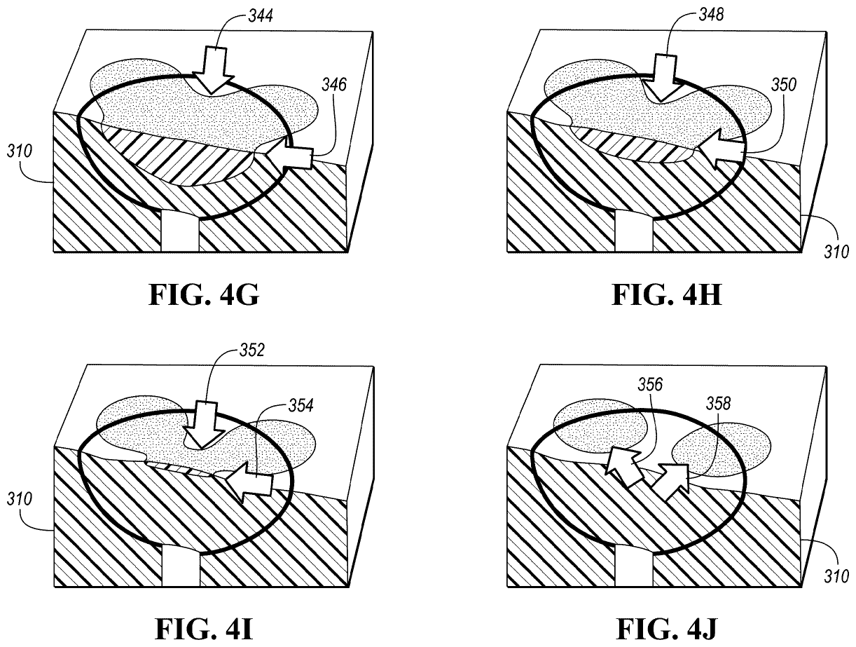

FIGS. 4A through 4J depict the SCR values for the first and second simulated cases for closing ventholes in a substrate. In the first simulated case, main laser 202 is used to form a melt pool that resolidifies to close a venthole. In the second simulated case, main laser 212 and supplemental lasers 214 are used to form a melt pool that resolidifies to close a venthole. In these embodiments, a relative SCR value is used to compare the results of the first and second simulated cases. The SCR defines the maximum SCR of the first and second simulated cases as 1.0 with the lower SCR values defined as a fraction of 1.0. The relative SCRs of the solidification paths of the first and second cases are determined and compared.

FIG. 4A is a schematic, perspective, cutaway view of substrate 300 having vent hole 302 and melt pool 304 formed above vent hole 302 using main laser 202 of the first simulated case. FIG. 4B is a schematic, cross-sectional view of substrate 300 having vent hole 302 and melt pool 304 formed above vent hole 302. As shown in FIGS. 4A and 4B, substrate 300 includes solid region 306 and resolidified region 308 located between melt pool 304 and solid region 306. FIGS. 4A and 4B depict substrate 300 with the application of main laser 202 after 1.5 time steps as shown in FIG. 3B.

FIG. 4C is a schematic, perspective cutaway view of substrate 310 having vent hole 312 and melt pool 314 formed above vent hole 312 using main laser 212 and supplemental lasers 214 of the second simulated case. FIG. 4D is a schematic, cross-sectional view of substrate 310 having vent hole 312 and melt pool 314 formed above vent hole 312. As shown in FIGS. 4C and 4D, substrate 310 includes solid region 316 and resolidified region 318 located between melt pool 314 and solid region 316. FIGS. 4C and 4D depict substrate 310 with the application of main laser 212 and supplemental lasers 214 after 1.5 time steps as shown in FIG. 3D.

The first simulated case has a relative SCR of 0.75 along the paths shown by arrows 320 and 322 and a relative SCR of 1.0 along the paths shown by arrows 324 and 326. The second simulated case has a relative SCR of 0.64 along paths shown by arrows 328, 330, 332, and 334. FIG. 4E is a schematic, perspective view of substrate 300 showing isometric solidification paths depicted by arrows 336 and 338 at time step 1.5. FIG. 4F is a schematic, perspective view of substrate 300 showing isometric solidification paths depicted by arrows 340 and 342 at time step 2.0. The first simulated case has a relative SCR of 1.0 along the paths depicted by arrows 336 and 338. The first simulated case has a relative SCR of 1.0 along the paths depicted by arrows 340 and 342. FIG. 4G is a schematic, perspective view of substrate 310 showing isometric solidification paths depicted by arrows 344 and 346 at time step 1.5 having relative SCR values of 0.64. FIG. 4H is a schematic, perspective view of substrate 310 showing isometric solidification paths depicted by arrows 348 and 350 at time step 2.0 having relative SCR values of 0.2. FIG. 4I is a schematic, perspective view of substrate 310 showing isometric solidification paths depicted by arrows 352 and 354 at time step 2.7 having relative SCR values of 0.15. FIG. 4J is a schematic, perspective view of substrate 310 showing isometric solidification paths depicted by arrows 356 and 358 at time step 3.0 having relative SCR values of 0.4.

From the data shown in FIGS. 4A-4J, it is observed that the second simulation case has slower relative SCRs than the first simulation case due to the additional laser heat input from supplemental lasers 214 slowing down the SCR. From the data shown in FIGS. 4E-4J, it is observed that the solidification paths change from the first simulation case to the first simulation case since a higher SCR is presented around the supplementary laser spots of supplemental lasers 214, and the final solidification domains are where the supplementary laser spots were applied. A comparison of FIGS. 4E and 4F with FIGS. 4G-4J depicts an alteration of the solidification path (e.g., a solidification path from the periphery to the center in FIGS. 4E and 4F to a solidification path from the center to the periphery laser spot locations in FIGS. 4G-4J.

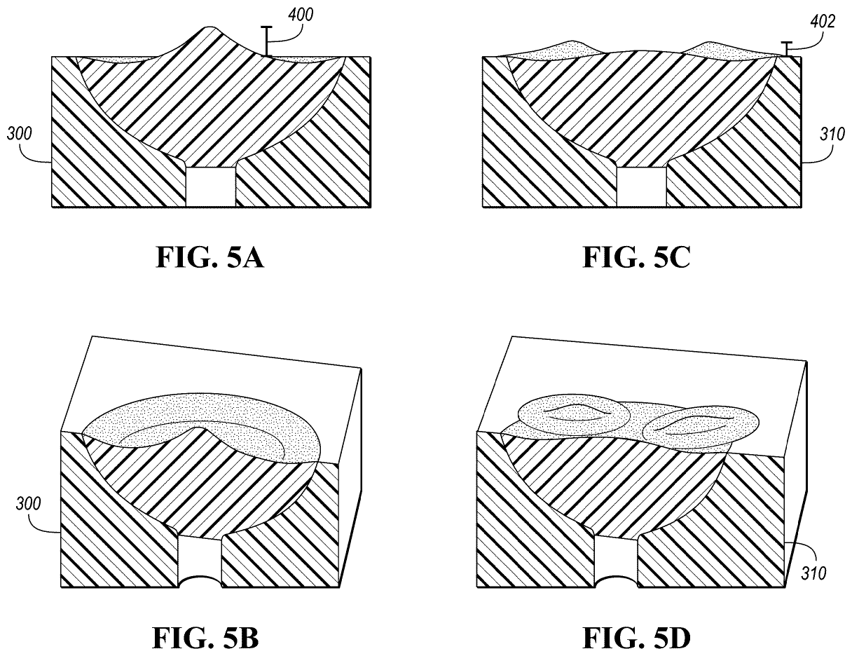

FIGS. 5A-5D depict a comparison of the final solidified surface morphology of substrate 300 and substrate 310. FIG. 5A is a schematic, cross-sectional view of substrate 300 showing a tip height 400 of 100% for the final solidified surface morphology. FIG. 5B is a schematic, cutaway view of substrate 300 showing the final solidified surface morphology. FIG. 5C is a schematic, cross-sectional view of substrate 310 showing a tip height 402 of 50% for the final solidified surface morphology. FIG. 5D is a schematic, cutaway view of substrate 310 showing the final solidified surface morphology. A surface tip height reduction is observed with the second simulation.

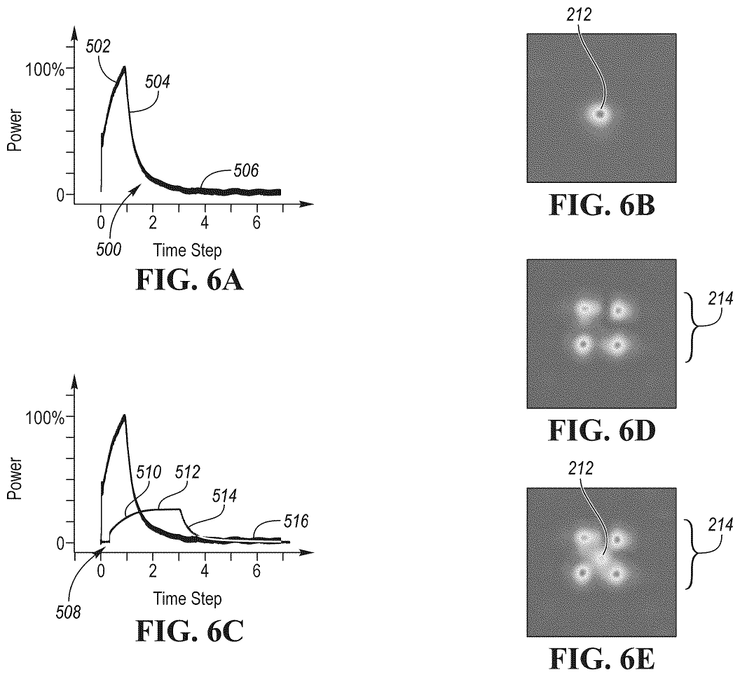

FIG. 6A is a graph plotting power as a function of time step for a primary laser (e.g., main laser 212) to obtain primary power curve 500. Primary power curve 500 includes first segment 502 where the power increases sharply, second segment 504 where the power decreases sharply, and third segment 506 where the power decreases gradually. FIG. 6B is an image depicting an end view of main laser 212. FIG. 6B depicts the relative intensity of main laser 212 with the darker regions having greater intensity than the lighter regions.

FIG. 6C is a graph plotting power as a function of time step for the primary laser (e.g., main laser 212) and one or more secondary lasers (e.g., one or more supplemental lasers 214) to obtain primary power curve 500 and secondary power curve 508. Secondary power curve 508 includes first segment 510 where the power increases gradually, second segment 514 where the power is constant, third segment 516 where the power decreases sharply, and fourth segment 518 where the power decreases gradually. FIG. 6D is an image depicting the relative intensity of supplemental lasers 214 with the darker regions having greater intensity than the lighter regions. FIG. 6E is an image depicting the relative intensity of main laser 212 and supplemental lasers 214 with the darker regions having greater intensity than lighter regions. As shown in FIG. 6E, the laser irradiation domains and/or the laser pulse time durations of main laser 212 and supplemental lasers 214 overlap.

Applying laser power using the power graphs of FIGS. 6A and 6C result in adequate sealing of vent holes. However, the application of laser power according to FIG. 6C does not produce a sharp surface tip as is produced according to the laser power of FIG. 6A. The experiments depicted by FIGS. 6A-6E support the concept that laser spots around a main laser may beneficially control surface morphology (e.g., may help reduce the height of a surface tip in the melting and solidification domain).

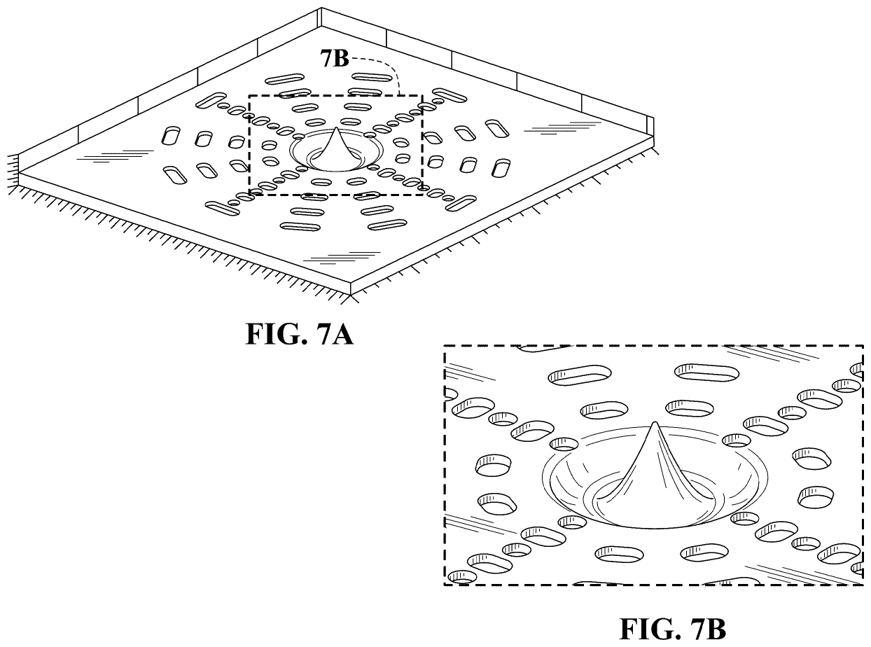

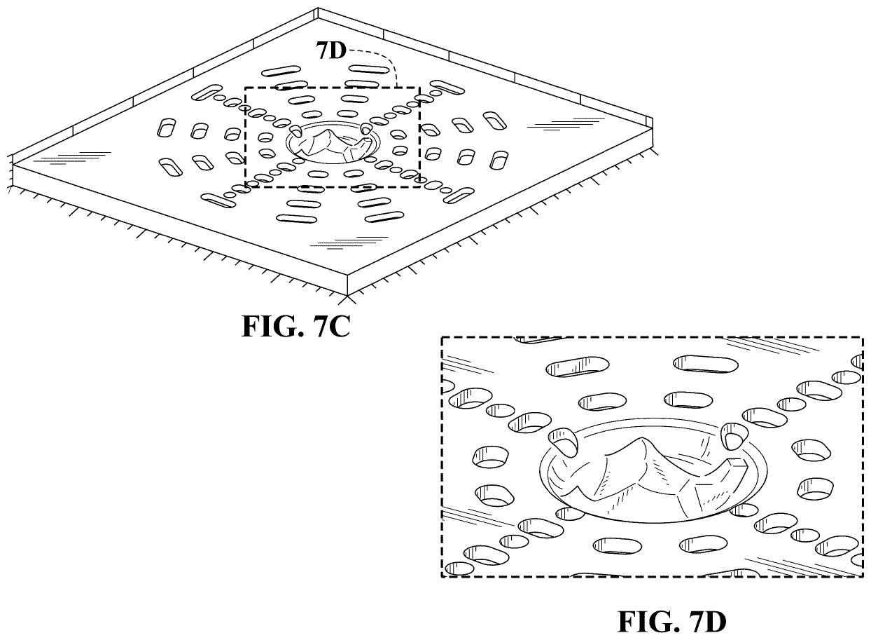

FIG. 7A is a first perspective view depicting the results of the vent hole closing process using the first simulation case. FIG. 7B is a second perspective view depicting the results of the vent hole closing process using the first simulation case. FIG. 7C is a first perspective view depicting the results of the vent hole closing process using the second simulation case. FIG. 7D is a second perspective view depicting the results of the vent hole closing process using the second simulation case. The notches shown around the center of melting and solidification domains of FIGS. 7A-7D are used for calibration of the measurement device and do not materially affect the experimental results.

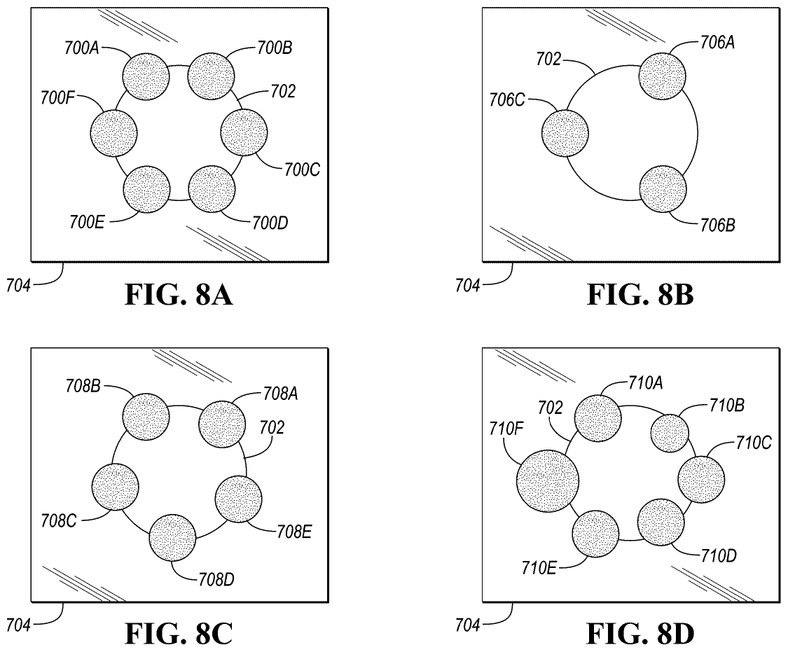

In one or more embodiments, one or more characteristics of one of the lasers may be adjusted to reduce asperity of the surface morphology during the vent hole sealing process. While the embodiment shown in FIGS. 6C-6E include four supplemental lasers, in other embodiments, a different number of supplemental lasers may be utilized (e.g., 3, 5, 6, 7, 8, or more or in a range thereof). For instance, FIG. 8A is a top view of six supplemental lasers 700A-700F evenly spaced around the periphery of main laser 702 above substrate 704. As shown in FIG. 8A, a portion of each of supplemental lasers 700A-700F overlap with a portion of main laser 702. The overlap is the same for each of the supplemental lasers, although in other embodiments, the overlap may be different (e.g., different center to center distances between a pair of supplemental lasers and the main laser). As shown in FIG. 8A, the size (e.g., the diameter) of each of the supplemental lasers 700A-700F is the same, although in other embodiments, the diameters may be different. As another example, FIG. 8B is a top view of three supplemental lasers 706A-706C evenly spaced around the periphery of main laser 702 above substrate 704. As shown in FIG. 8B, a portion of each of supplemental lasers 706A-706C overlap with a portion of main laser 702. FIG. 8C is a top view of six supplemental lasers 708A-708F unevenly spaced around the periphery of main laser 702 above substrate 704. The uneven spacing may apply to three or more of the supplemental lasers. FIG. 8D is a top view of six supplemental lasers 710A-710F unevenly spaced around the periphery of main laser 702 where the supplemental lasers 710A-710F have varying diameters. Two or more of the supplemental lasers may have varying diameters.

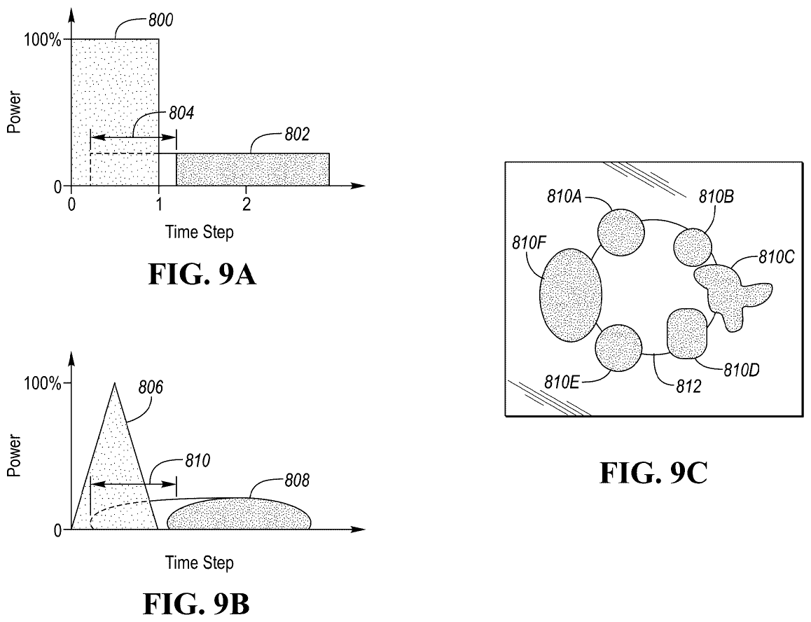

Other characteristics of one or more of the lasers that may be adjusted to reduce asperity of the surface morphology during the vent hole sealing process include varying laser temporal and/or energy profiles. In one or more embodiments, the power of the main and/or supplemental lasers may be constant while different between the main laser and the supplemental lasers. In one or more embodiments, the supplemental laser temporal profile may overlap or be spaced apart from the temporal profile of the main laser. FIG. 9A depicts a graph showing main laser profile 800 and supplemental laser profile 802 where the supplemental laser profile 802 may overlap or be spaced apart from main laser profile 800 as shown by arrow 804. The time overlap may be 0% to 100% (e.g., full overlap). In one or more embodiments, 100% overlap means the supplemental laser profile is longer than the main laser profile, and the supplemental laser profile is fully overlapped with the main laser profile at the entire time step duration of the main laser profile. The time gap may be 0% to 100% of the time step duration of the main laser.

In one or more embodiments, the power profiles of the main and supplemental lasers are not constant. For example, FIG. 9B depicts a graph showing main laser profile 806 and supplemental laser profile 808 where the power over time is non-constant. As shown by arrow 804 of FIG. 9B, supplemental laser profile 808 may overlap or be spaced apart from main laser profile 806. Main laser profile 806 has a triangular shape where the power increases and then decreases along the time step of the application of power by main laser profile 806. In other embodiments, the power may start at a higher value and decrease through the time step, and in yet other embodiments, the power pay start at a lower value and increase through the time step. The increases and/or decreases in the power may follow a linear, sinusoidal, stepped, saw toothed, or curved trajectory. Supplemental laser profile 806 has a curved trajectory as shown in FIG. 9C.

One or more of the supplemental lasers may take on different shapes and may not be limited to a circular irradiation. As non-limiting examples, the irradiation pattern may be oval, near-square shaped, or an irregular shape. FIG. 9C depicts a top view of six supplemental lasers 810A-810F spaced around the periphery of main laser 812 and having varying shapes. For example, supplemental laser 810C has an irregular shape, supplemental laser 810D has a near-square shape, and supplemental laser 810F has an oval shape.

The following applications are related to the present application: U.S. patent application Ser. No. 17/863,659 filed on Jul. 13, 2022, U.S. patent application Ser. No. 17/863,665 filed on Jul. 13, 2022, and U.S. patent application Ser. No. 17/863,669 filed on Jul. 13, 2022, which are each incorporated by reference in their entirety herein.

The processes, methods, or algorithms disclosed herein can be deliverable to/implemented by a processing device, controller, or computer, which can include any existing programmable electronic control unit or dedicated electronic control unit. Similarly, the processes, methods, or algorithms can be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms can also be implemented in a software executable object. Alternatively, the processes, methods, or algorithms can be embodied in whole or in part using suitable hardware components, such as Application Specific Integrated Circuits (ASICs), Field-Programmable Gate Arrays (FPGAs), state machines, controllers or other hardware components or devices, or a combination of hardware, software and firmware components.

While exemplary embodiments are described above, it is not intended that these embodiments describe all possible forms encompassed by the claims. For example, while certain disclosed embodiments describe simulations and experiments about laser sealing of a vent hole with surface tip reduction, one or more embodiments may be applied to surface tip reduction for flat substrates (e.g., those without vent holes) and/or slightly tilted substrate surfaces. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, case of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. A method for controlling surface asperity during laser sealing of a membrane vent hole, the method comprising:
applying a main pulse from a main laser to the membrane vent hole at a first time, the main pulse having a main pulse cross-sectional shape, a main pulse power profile, and a main pulse duration; and
applying one or more supplemental pulses from one or more supplemental lasers to the membrane vent hole at a second time later than the first time, the one or more supplemental pulses having supplemental pulse cross-sectional shape(s), supplemental pulse power profile(s), and supplemental pulse duration(s),
the first and second applying steps form a seal over the membrane vent hole, the seal including a seal surface having a controlled surface asperity characteristic.

2. The method of claim 1, wherein the main pulse cross-sectional shape is a circular shape having a main diameter and the supplemental pulse shape(s) are circular shapes having supplemental diameter(s) less than the main diameter.

3. The method of claim 2, wherein the supplemental diameter(s) are less than the main diameter by a percentage of 5% to 90%.

4. The method of claim 1, wherein the main pulse power profile has a main peak power and the supplemental pulse power profile(s) have supplemental peak power(s) less than the main peak power.

5. The method of claim 4, wherein the supplemental peak power(s) are less than the main peak power by a percentage of 5% to 60%.

6. The method of claim 1, wherein the one or more supplemental pulse(s) are located along a periphery of the main laser pulse.

7. The method of claim 6, wherein the one or more supplemental pulse(s) overlap the main laser pulse around the periphery thereof.

8. The method of claim 6, wherein the one or more supplemental pulses include two or more supplemental pulses spaced evenly around the periphery of the main pulse.

9. The method of claim 1, wherein the second time overlaps the main pulse duration.

10. The method of claim 1, wherein the second time is after the main pulse duration.

11. The method of claim 1, wherein a time gap exists between the main pulse duration and the supplemental pulse duration(s).

12. The method of claim 1, wherein the main pulse power profile includes a constant main power and the supplemental pulse power profile(s) include constant supplemental power(s).

13. The method of claim 1, wherein the one or more supplemental pulses include a first supplemental pulse having a circular shape and a second supplemental pulse having a non-circular shape.

14. The method of claim 1, wherein the one or more supplemental pulses are non-overlapping.

15. The method of claim 1, wherein the controlled surface asperity characteristic is a reduced surface asperity height.

16. A method for controlling surface asperity during laser sealing of a membrane vent hole, the method comprising:
applying a main pulse from a main laser to the membrane vent hole at a first time, the main pulse having a main pulse cross-sectional shape, a main pulse power profile, and a main pulse duration; and
applying one or more supplemental pulses from one or more supplemental lasers to the membrane vent hole at a second time later than the first time, the one or more supplemental pulses having supplemental pulse cross-sectional shape(s), supplemental pulse power profile(s), and supplemental pulse duration(s), the one or more supplemental pulses include a first supplemental pulse, a second supplemental pulse, a third supplemental pulse, and a fourth supplemental pulse,
the first and second applying steps form a seal over the membrane vent hole, the seal including a seal surface having a controlled surface asperity characteristic.

17. The method of claim 16, wherein the first, second, third, and fourth supplemental pulses are spaced evenly around a periphery of the main pulse.

18. The method of claim 16, wherein the first, second, third, and fourth supplemental pulses have circular shapes.

19. A method for controlling surface asperity during laser sealing of a membrane vent hole, the method comprising:
applying a main pulse from a main laser to the membrane vent hole at a first time, the main pulse having a main pulse cross-sectional shape, a main pulse non-constant power profile, and a main pulse duration; and
applying one or more supplemental pulses from one or more supplemental lasers to the membrane vent hole at a second time later than the first time, the one or more supplemental pulses having supplemental pulse cross-sectional shape(s), supplemental pulse non-constant power profile(s), and supplemental pulse duration(s),
the first and second applying steps form a seal over the membrane vent hole, the seal including a seal surface having a controlled surface asperity characteristic.

20. The method of claim 19, wherein the main pulse non-constant power profile has a triangular shape.
